(19) United States
(12) Patent Application Publication
(10) Pub. No.: US 2026/0165145 A1
(43) Pub. Date: Jun. 11, 2026

(54) SEMICONDUCTOR PACKAGE

(71) Applicant: Samsung Electronics Co., Ltd., Suwon-si (KR)

(72) Inventors: Inho SEO, Suwon-si (KR); KANG GYUNE LEE, Suwon-si (KR); GI-BBEUM MUN, Suwon-si (KR); HYEON HWANG, Suwon-si (KR)

(21) Appl. No.: 19/251,604

(22) Filed: Jun. 26, 2025

(30) Foreign Application Priority Data
Dec. 6, 2024 (KR) 10-2024-0180751

(51) Int. Cl. H01L 23/544; H01L 21/56; H01L 23/00; H01L 23/29; H01L 23/31; H01L 23/498

(52) U.S. Cl. CPC H10W 46/00; H10W 74/016; H10W 74/121; H10W 46/607; H10W 74/47; H10W 90/701; H10W 90/754

(57) ABSTRACT

A semiconductor package may include a substrate, a semiconductor chip on the substrate, a first molding layer covering the semiconductor chip on the substrate, a second molding layer on the first molding layer and having a cavity formed therein, and a metal pattern between the first molding layer and the second molding layer and in the cavity. The metal pattern may include a first portion having an upper surface positioned at the same level as or higher level than an upper surface of the second molding layer.

### CROSS-REFERENCE TO RELATED APPLICATIONS

This U.S. non-provisional patent application claims priority under 35 U.S.C. § 119 to Korean Patent Application No. 10-2024-0180751 filed on Dec. 6, 2024, in the Korean Intellectual Property Office, the entire contents of which are hereby incorporated by reference.

### BACKGROUND OF THE INVENTION

The inventive concept relates to a semiconductor package.

A semiconductor package may be provided to implement an integrated circuit chip for use in electronic products. A semiconductor package may be configured such that a semiconductor chip is mounted on a printed circuit board. Bonding wires or bumps may be used to electrically connect the semiconductor chip to the printed circuit board. With developments of the electronic industry, various studies have been conducted to improve reliability and minimization of semiconductor packages.

### SUMMARY

An object of the inventive concept is to provide a semiconductor package with improved marking visibility.

The inventive concept is not limited to the object mentioned above, and other technical benefits not mentioned above may be clearly understood by those skilled in the art from the description below.

A semiconductor package according to some embodiments of the inventive concept may include a substrate, a semiconductor chip on the substrate, a first molding layer covering the semiconductor chip on the substrate, a second molding layer on the first molding layer and having a cavity formed therein, and a metal pattern between the first molding layer and the second molding layer and in the cavity, wherein the metal pattern includes a first portion having an upper surface positioned at the same level as or higher level than an upper surface of the second molding layer.

A semiconductor package according to some embodiments of the inventive concept may include a substrate, a semiconductor chip on the substrate, a first molding layer covering the semiconductor chip on the substrate and including a protrusion protruding upward, a second molding layer on the first molding layer and having a cavity formed therein that corresponding to the protrusion, and a metal pattern on the protrusion in the cavity, wherein an uppermost end of the metal pattern is disposed at a level equal to or higher than an upper surface of the second molding layer.

A semiconductor package according to some embodiments of the inventive concept may include a substrate, a semiconductor chip on the substrate, a bonding wire electrically connecting the substrate and the semiconductor chip, a first molding layer covering the semiconductor chip on the substrate and including a protrusion protruding upward, a second molding layer on the first molding layer and having a cavity formed therein that vertically overlaps the protrusion, a metal pattern having a first portion disposed on an upper surface of the protrusion and a second portion between the first molding layer and the second molding layer and, and a connection terminal on a lower surface of the substrate, wherein an uppermost end of the metal pattern is disposed at a level equal to or higher than an upper surface of the second molding layer.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1A is a cross-sectional view of a semiconductor package according to one embodiment of the inventive concept.

FIG. 1B is a cross-sectional view of a semiconductor package according to another embodiment of the inventive concept.

FIG. 2 is an enlarged view of portion ‘P’ of FIG. 1A.

FIG. 3 is a flowchart illustrating a manufacturing method according to embodiments of the inventive concept.

FIGS. 4 to 9 are cross-sectional views illustrating a manufacturing method according to embodiments of the inventive concept.

### DETAILED DESCRIPTION

Hereinafter, embodiments according to the inventive concept will be described with reference to the attached drawings, in which various embodiments are shown. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

As used herein, the terms “material continuity” and “without a break in continuity” may refer to structures, patterns, and/or layers that are formed at the same time and of the same material, without a break in the continuity of the material of which they are formed. As one example, structures, patterns, and/or layers that are in “material continuity” or “materially in continuity” may be homogeneous monolithic structures.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

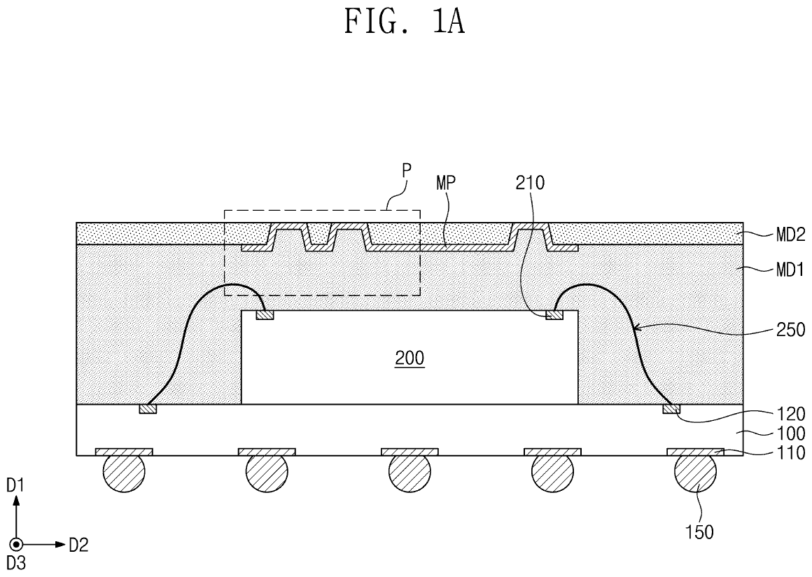

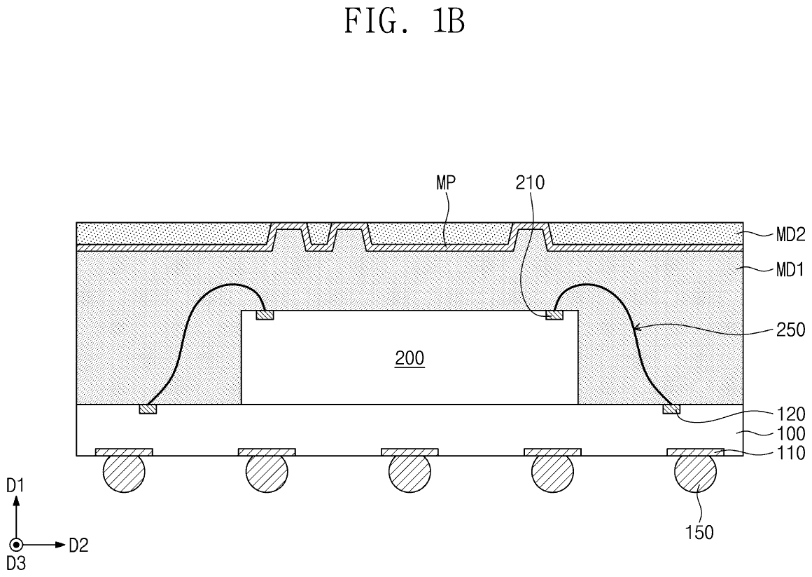

FIG. 1A is a cross-sectional view of a semiconductor package according to an embodiment of the inventive concept. FIG. 2 is an enlarged view of portion ‘P’ of FIG. 1A.

Referring to FIG. 1A, a semiconductor package according to an embodiment of the inventive concept may include a substrate 100, a semiconductor chip 200, a first molding layer MD1, a second molding layer MD2, and a metal pattern MP.

The substrate 100 may be one of various types of substrates, such as a printed circuit board (PCB), a flexible substrate, or a tape substrate, for example. As another example, the substrate 100 may be a redistribution substrate including a redistribution pattern and insulating layers. In the following description specification, a direction perpendicular to an upper surface of the substrate 100 may be defined as a first direction D1 (e.g., a vertical direction). A second direction D2 and a third direction D3 may be defined as directions parallel to the upper surface of the substrate 100 (e.g., horizontal directions), and the second direction D2 and the third direction D3 may be orthogonal to each other.

Lower pads 110 may be provided on the lower surface of the substrate 100. The lower pads 110 may be spaced apart from each other horizontally (e.g., in the second direction D2 or the third direction D3). Upper pads 120 may be provided on the upper surface of the substrate 100. The upper pads 120 may be spaced apart from each other horizontally (e.g., in the second direction D2 or the third direction D3). The lower pads 110 and the upper pads 120 may include, for example, metal. The lower pads 110 and the upper pads 120 may include at least one of copper, aluminum, tungsten, and titanium, but are not limited thereto. Although not shown, the lower pads 110 and the upper pads 120 may be electrically connected to each other through a wiring in the substrate 100.

Connection terminals 150 may be disposed on a lower surface of the substrate 100. The connection terminals 150 may be spaced apart from each other in the second direction D2. The connection terminals 150 may include a solder material. For example, the connection terminals 150 may include tin (Sn), bismuth (Bi), lead (Pb), silver (Ag), or an alloy thereof.

The semiconductor chip 200 may be disposed on the substrate 100. The semiconductor chip 200 may be mounted on the substrate 100. Although not shown, connection terminals (not shown) may be disposed between the semiconductor chip 200 and an upper surface of the substrate 100.

The semiconductor chip 200 may be, for example, a memory chip or a logic chip. The memory chip may be, for example, a volatile memory chip such as a dynamic random access memory (DRAM) or a static random access memory (SRAM), or a nonvolatile memory chip such as a phase-change random access memory (PRAM), an magnetoresistive random access memory (MRAM), a ferroelectric random access memory (FeRAM), or a resistive random access memory (RRAM). The logic chip may be, for example, a microprocessor such as a central processing unit (CPU), a graphic processing unit (GPU), or an application processor (AP), an analog device, or a digital signal processor. As another example, the semiconductor chip 200 may be one of a vertical stack of semiconductor chips.

Chip pads 210 may be provided on the upper surface of the semiconductor chip 200. The chip pads 210 may be spaced apart horizontally (e.g., in the second direction D2 or the third direction D3). The chip pads 210 may include, for example, metal. The chip pads 210 may include at least one of copper, aluminum, tungsten, and titanium, but are not limited thereto.

A semiconductor package according to embodiments of the inventive concept may further include bonding wires 250. The bonding wires 250 may be provided on the substrate 100. The bonding wires 250 may electrically connect the upper pads 120 of the substrate 100 and the chip pads 210 of the semiconductor chip 200. The bonding wires 250 may be covered by a first molding layer MD1 described below, and may be vertically spaced from a second molding layer MD2. The bonding wires 250 may include, for example, a metal, and may include, for example, at least one of copper, aluminum, tungsten, and titanium, but are not limited thereto.

The first molding layer MD1 may be disposed on the substrate 100. The first molding layer MD1 may cover an upper surface of the substrate 100 and the semiconductor chip 200. The first molding layer MD1 may cover the bonding wires 250. For example, the first molding layer MD1 may include an epoxy molding compound (EMC). For example, the first molding layer MD1 may include an epoxy resin, a first filler, and carbon black. The first filler may include, for example, at least one of silicon oxide and aluminum oxide.

Referring to FIG. 1A and FIG. 2, the first molding layer MD1 may include a protrusion MD1_P protruding upward from an upper surface of the first molding layer MD1. The protrusion MD1_P may be a portion protruding vertically from the first molding layer MD1. For example, a plurality of protrusions MD1_P may be provided, and may be horizontally spaced from each other.

The second molding layer MD2 may be disposed on the first molding layer MD1. The second molding layer MD2 may have cavities CAV formed therein (e.g., recesses in a lower surface of the second molding layer MD2 which may extend vertically through the second molding layer MD2). For example, a plurality of cavities CAV may be formed in the second molding layer MD2, and the cavities CAV may be horizontally spaced from each other. Inner walls INR of the second molding layer MD2 may define walls of the cavities CAV.

The second molding layer MD2 may include, for example, an epoxy molding compound (EMC). For example, the second molding layer MD2 may include an epoxy resin, a second filler, and carbon black. The second filler may include, for example, at least one of silicon oxide and aluminum oxide. The second filler may be the same or a different material as a first filler of the first molding layer. For example, the types of fillers included in the second molding layer MD2 and the first molding layer MD1 may be the same or different from each other. When the first molding layer MD1 and the second molding layer MD2 include the same type of filler, the first molding layer MD1 and the second molding layer MD2 may not have a discernable interface between them. When the first molding layer MD1 and the second molding layer MD2 include different types of fillers, an interface may be formed therebetween and may be apparent.

The locations of protrusions MD1_P of the first molding layer MD1 may correspond to the cavities CAV of the second molding layer MD2, respectively. For example, the protrusions MD1_P of the first molding layer MD1 may vertically overlap the cavities CAV of the second molding layer MD2, respectively. The protrusions MD1_P of the first molding layer MD1 may extend into the cavities CAV of the second molding layer MD2 (a protrusion MD1_P of the first molding layer may extend in a corresponding cavity CAV of the second molding layer MD2). For example, the protrusions MD1_P may be defined as portions of the first molding layer MD1 that protrudes into the cavities CAV of the second molding layer MD2, respectively. For example, each protrusion MD1_P may be horizontally spaced from the second molding layer MD2 (e.g., there may be a horizontal gap between an outer wall of a protrusion MD1_P and an inner wall INR of the second molding layer MD2). An upper surface of the protrusion MD1_P may be positioned at a lower vertical level than an upper surface of the second molding layer MD2.

A vertical length T1 of the protrusion MD1_P may have a value of, for example, between 5 μm and 50 μm. The vertical length T1 of the protrusion MD1_P may be defined as a length in the first direction D1 between the uppermost and lowermost ends of the protrusion MD1_P (e.g., a distance the protrusion protrudes from the upper surface of the first molding layer MD1). A thickness T3 of the second molding layer MD2 may be greater than the vertical length T1 of the protrusion MD1_P. For example, the thickness T3 of the second molding layer MD2 may have a value of, for example, between 5 μm and 50 μm, and may be greater than the vertical length T1 of the protrusion MD1_P.

A metal pattern MP covering the walls of the cavities CAV may be provided (e.g., covering the inner walls of the second molding layer MD2). The metal pattern MP may be formed as an integral body, for example. However, it is not limited thereto, and as another embodiment, a plurality of metal patterns MP may be formed and provided respectively in the cavities CAV.

A first portion of the metal pattern MP may be provided in a cavity CAV of the second molding layer MD2. A second portion of the metal pattern MP may extend onto a lower surface of the second molding layer MD2 and be disposed between the second molding layer MD2 and the first molding layer MD1. The second portion of the metal pattern MP may partially cover a lower surface of the second molding layer MD2, but may not completely cover the lower surface of the second molding layer MD2. As a result, a portion of the lower surface of the second molding layer MD2 may be in contact with the first molding layer MD1. The metal pattern MP may include, for example, at least one of titanium (Ti) and nickel (Ni).

Referring to FIG. 2, as an embodiment of the inventive concept, the metal pattern MP may include a first portion MP1 on an upper surface of the protrusion MD1_P, a second portion MP2 on a sidewall of the protrusion MD1_P, and a third portion MP3 on the lower surface of the second molding layer MD2. The first to third portions MP1, MP2, and MP3 may be connected to each other without an interface therebetween (e.g., they may each be part of a single material without a break in continuity).

The first portion MP1 of the metal pattern MP may cover the upper surface of the protrusion MD1_P and may have an upper and/or lower surface parallel to the upper surface of the substrate 100. The first portion MP1 may be disposed in the cavity CAV of the second molding layer MD2 and may be disposed on the upper surface of the protrusion MD1_P of the first molding layer MD1. For example, the upper surface of the first portion MP1 may be exposed to the outside without being covered by the first or second molding layer MD1 or MD2 (e.g., may be exposed by the first or second molding layer). For example, the upper surface of the first portion MP1 may be positioned at the same level as the upper surface of the second molding layer MD2, or may be positioned at a higher level than the upper surface of the second molding layer MD2. The upper surface of the first portion MP1 may be the uppermost end of the metal pattern MP.

The metal pattern MP may include a metal having high visibility (e.g., titanium or nickel) relative to the second molding layer MD2 (e.g., has a high contrast with the material of the second molding layer MD2 at an inspection wavelength, such as the visible light spectrum between 380 nm and 750 nm). The metal may have a higher visibility due to light being reflected rather than being absorbed. The uppermost end (or the first portion MP1) exposed to the outside of the metal pattern MP may be a marking pattern of the semiconductor package. As a result, the marking visibility of the semiconductor package may be improved relative to a material with lower visibility.

The second portion MP2 of the metal pattern MP may be connected to the first portion MP1 of the metal pattern MP, and may be disposed on a sidewall of the protrusion MD1_P. The second portion MP2 may cover the sidewall of the protrusion MD1_P. The second portion MP2 may be in contact with the sidewall of the protrusion MD1_P and the inner sidewall INR of the second molding layer MD2, respectively.

The third portion MP3 of the metal pattern MP may be connected to the second portion MP2, and may be disposed between the first molding layer MD1 and the second molding layer MD2. For example, the third portion MP3 may be a portion extending onto the lower surface of the second molding layer MD2. A level of the third portion MP3 of the metal pattern MP may be positioned at a level lower than a level of the first portion MP1 by the thickness T3 of the second molding layer MD2. As the third portion MP3 of the metal pattern MP is positioned at a vertical level lower than the first portion MP1 and is covered by the second molding layer MD2 (e.g., not exposed by the second molding layer MD2), the third portion MP3 may not be visible or may have low visibility relative to the first portion MP1 and is no used as a marking pattern.

The metal pattern MP may have a substantially uniform thickness in the vertical direction. For example, a thickness T2 of the metal pattern MP may have a value of 10 nm or more and 1 μm or less.

FIG. 1B is a cross-sectional view of a semiconductor package according to another embodiment of the inventive concept. For the sake of simplicity, descriptions of technical features identical to those of the semiconductor device described above may be omitted, and differences between the embodiments will be described.

Referring to FIG. 1B, the metal pattern MP may be disposed between the first molding layer MD1 and the second molding layer MD2, and thus the first molding layer MD1 and the second molding layer MD2 may be spaced apart from each other (e.g., separated by the thickness of the metal pattern MP). For example, the third portion MP3 of the metal pattern MP described with reference to FIG. 2 may completely cover the lower surface of the second molding layer MD2. Furthermore, the metal pattern MP may completely cover the upper surface of the first molding layer MD1, and the first molding layer MD1 and the second molding layer MD2 may be vertically spaced apart from each other.

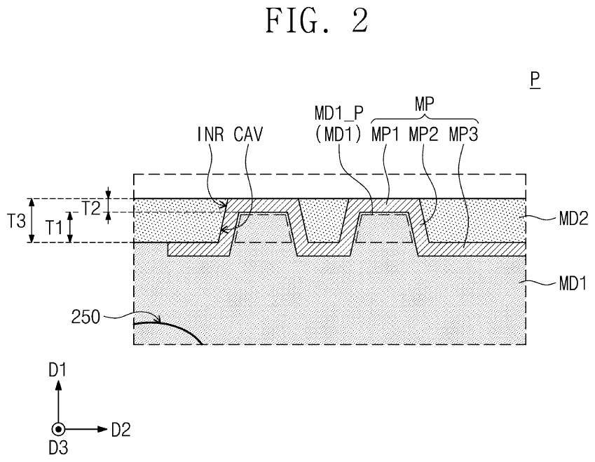

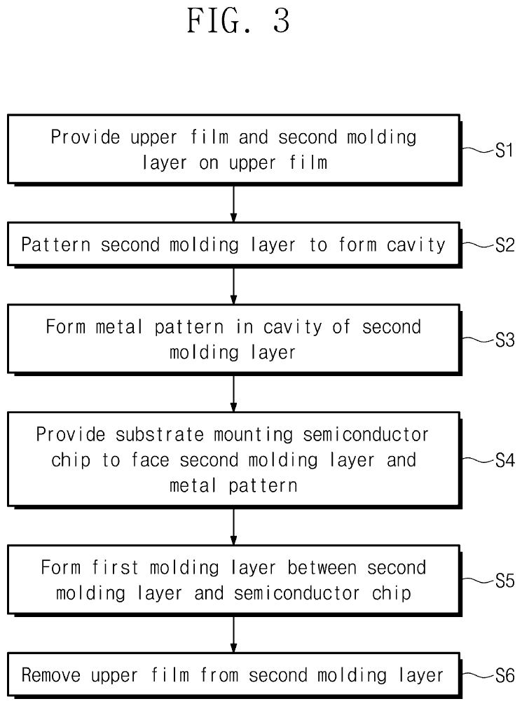

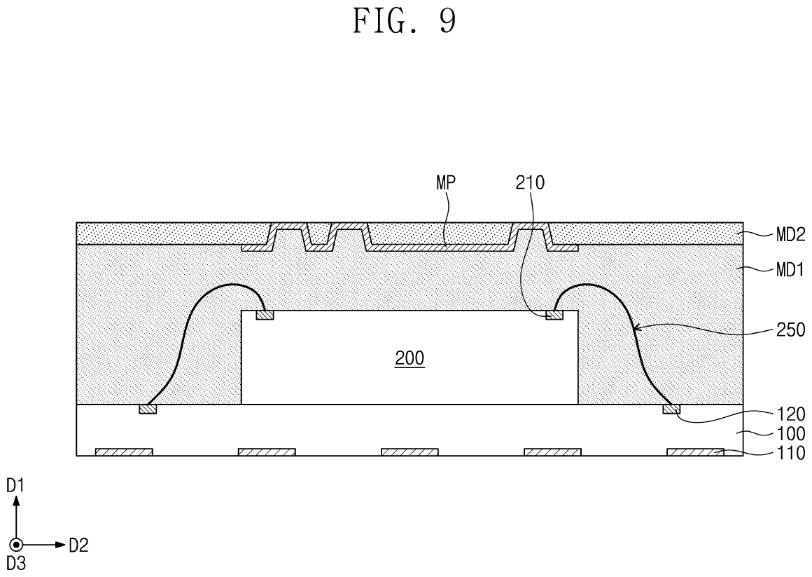

FIG. 3 is a flowchart illustrating a manufacturing method according to embodiments of the inventive concept. FIGS. 4 to 9 are cross-sectional views illustrating a manufacturing method according to embodiments of the inventive concept.

Referring to FIGS. 3 and 4, providing an upper film 10 and a second molding layer MD2 on the upper film 10 may be performed in S1. The upper film 10 may be, for example, a polymeric layer, and may be one of a polyester (PET) layer, a polypropylene (PP) layer, and a polycarbonate (PC) layer. The second molding layer MD2 may include, for example, an epoxy resin, a second filler, and carbon black. The second filler may include, for example, at least one of silicon oxide and aluminum oxide.

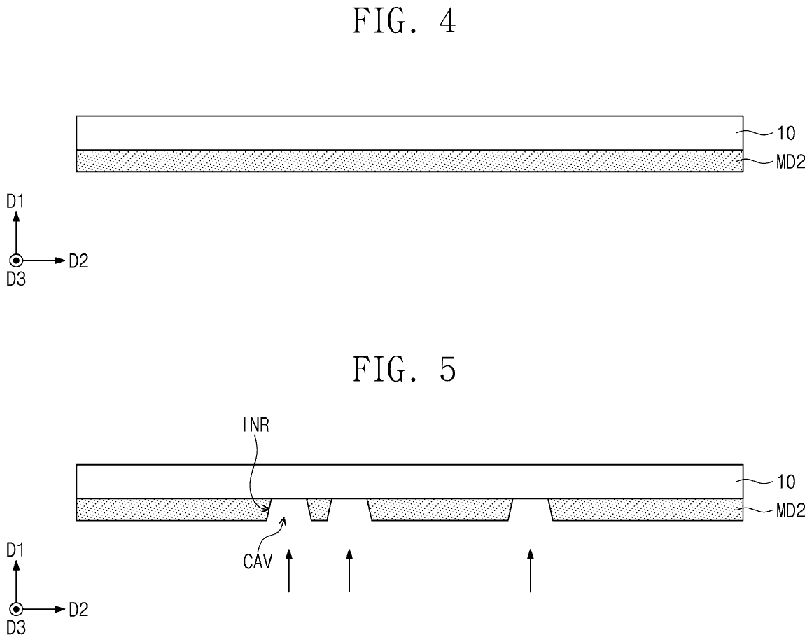

Referring to FIGS. 3 and 5, patterning the second molding layer MD2 to form a cavity CAV may be performed in S2. Patterning the second molding layer MD2 may be performed using, for example, laser patterning. The second molding layer MD2 may be patterned so that a surface of the upper film 10 is exposed, and the cavities CAV may be formed in the second molding layer MD2. Inner walls INR of the second molding layer MD2 may be exposed through the cavities CAV.

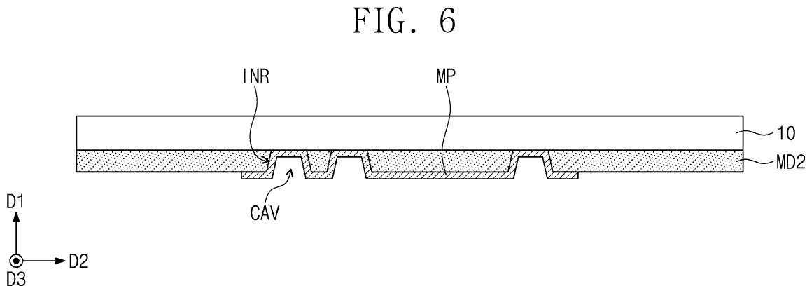

Referring to FIGS. 3 and 6, forming a metal pattern MP on the cavity CAV of the second molding layer MD2 may be performed in S3. The metal pattern MP may be formed using, for example, at least one of a spray method, a plating method, and a chemical vapor deposition (CVD). The metal pattern MP may fill at least a portion of each of the cavities CAV and cover the inner walls INR of the second molding layer MD2. The metal pattern MP may be formed, for example, by spraying, to cover the cavities CAV, and may partially cover a lower surface of the second molding layer MD2. As another example, unlike the example of FIG. 6, the metal pattern MP may be formed to entirely cover the lower surface of the second molding layer MD2. As still another example, metal patterns MP may be formed in the cavities CAV, respectively, and a plurality of the metal patterns MP may be provided.

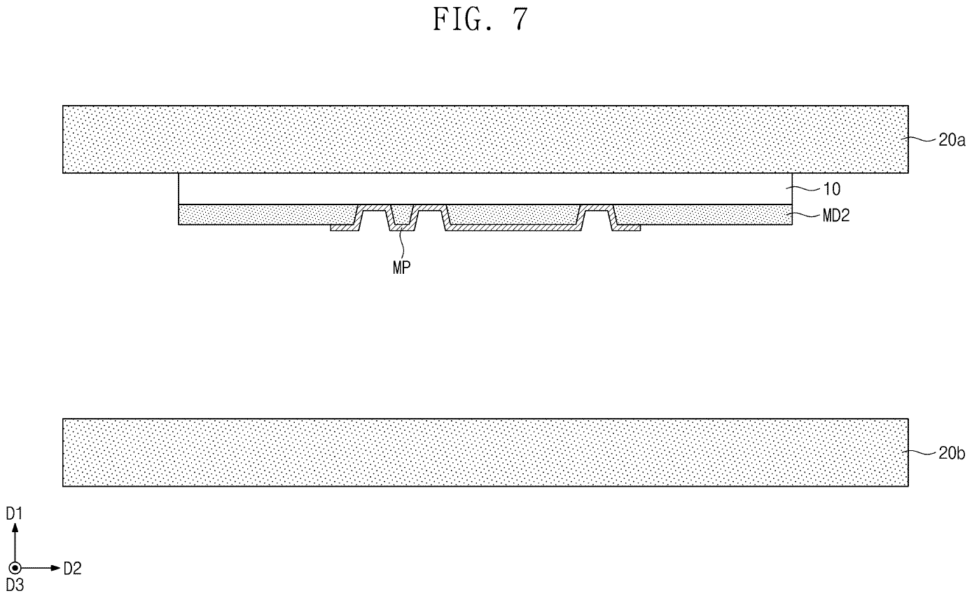

Referring to FIG. 7, the upper film 10, the second molding layer MD2, and the metal pattern MP may be inserted between first and second molds 20a and 20b. For example, one surface of the upper film 10 may be adhered to the first mold 20a. The second molding layer MD2 and the metal pattern MP may face the second mold 20b.

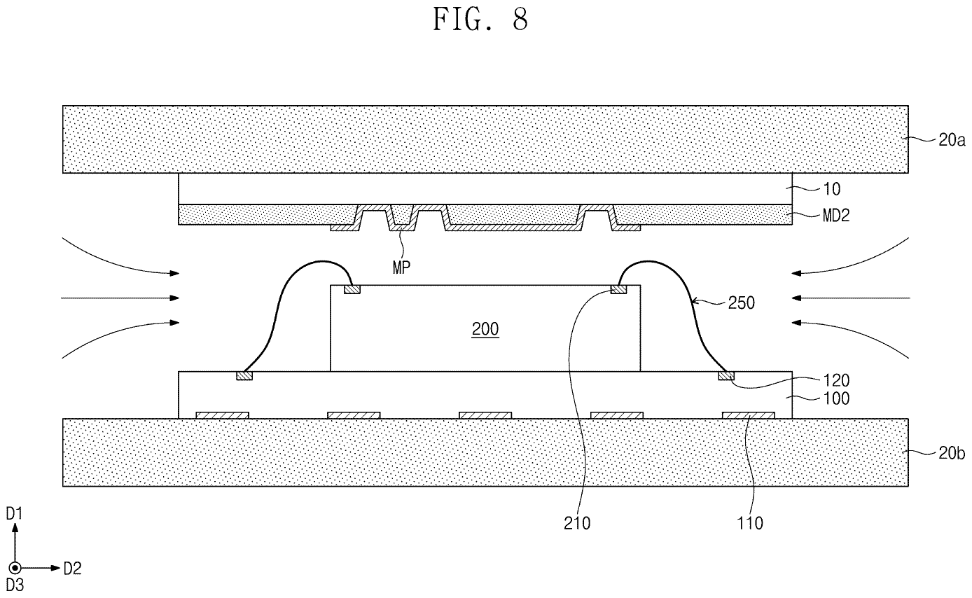

Referring to FIG. 3 and FIG. 8, providing a substrate 100 including a semiconductor chip 200 mounted thereon to face the second molding layer MD2 and the metal pattern MP may be performed in S4.

The substrate 100 including the semiconductor chip 200 mounted thereon may be provided. The semiconductor chip 200 may be mounted on the substrate 100 through a conventional process. The semiconductor chip 200 and the substrate 100 may be electrically connected to each other through bonding wires 250.

The semiconductor chip 200 and the substrate 100 may be inserted between the first and second molds 20a and 20b. For example, the substrate 100 may be placed on the second mold 20b. The semiconductor chip 200 and the substrate 100 may be placed to correspond to the upper film 10 (e.g., vertically aligned). Accordingly, the semiconductor chip 200 and the substrate 100 may face the second molding layer MD2 and the metal pattern MP. An adhesive layer (not shown) or an adhesive tape (not shown) may be disposed between the substrate 100 and the second mold 20b. Subsequently, a molding member may be injected between the first and second molds 20a and 20b through an injector (not shown). The molding member may include, for example, epoxy resin, a first filler, and carbon black.

Referring to FIGS. 3, 8, and 9, forming a first molding layer MD1 between the second molding layer MD2 and the semiconductor chip 200 may be performed in S5. The forming of the first molding layer MD1 may include injecting or inserting a molding member between the first and second molds 20a and 20b, and curing the molding member.

After the first molding layer MD1 is formed, a semiconductor package including the substrate 100, the semiconductor chip 200, the first and second molding layers MD1 and MD2, and the metal pattern MP may be de-molded from the first and second molds 20a and 20b. In the process of demolding the semiconductor package, removing the upper film 10 on the second molding layer MD2 may be performed in S6. As the upper film 10 on the second molding layer MD2 is removed, a portion of the upper surface of the metal pattern MP and the upper surface of the second molding layer MD2 may be exposed to the outside.

Referring again to FIG. 1, connection terminals 150 may be formed on a lower surface of the substrate 100. The connection terminals 150 may be formed on the lower pads 110 respectively through conventional processes.

If patterning for forming the metal pattern MP were performed on the semiconductor chip 200 and the first molding layer MD1 covering the semiconductor chip 200 without using embodiments of the inventive concept, laser marking for patterning may cause thermal damage to the semiconductor chip 200. As a result, reliability of the semiconductor chip 200 may be reduced. However, according to embodiments of the inventive concept, the patterning process for forming the metal pattern MP may be performed first on the upper film 10 and the second molding layer MD2, and thus the above-described problem may not occur. As a result, the reliability of the semiconductor package may be improved.

The semiconductor package according to the inventive concept may include the metal pattern disposed between the first molding layer and the second molding layer. A portion of the metal pattern may be disposed on the upper end of the semiconductor package and exposed to the outside. The portion of the exposed metal pattern may be recognized as a marking pattern, thereby improving the marking visibility of the semiconductor package.

Furthermore, in the manufacturing process of the semiconductor package according to the inventive concept, the patterning process for marking may be performed on the upper film and the second molding layer on the upper film. For example, the patterning process for marking may not be performed on the semiconductor chip, and thus the semiconductor chip may not be damaged by the patterning process. As a result, the reliability of the semiconductor package may be improved.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A semiconductor package comprising:
a substrate;
a semiconductor chip on the substrate;
a first molding layer covering the semiconductor chip on the substrate;
a second molding layer on the first molding layer and having a cavity formed therein; and
a metal pattern between the first molding layer and the second molding layer and in the cavity,
wherein the metal pattern includes a first portion having an upper surface positioned at the same level as or at a level higher than an upper surface of the second molding layer.

2. The semiconductor package of claim 1, wherein the metal pattern includes at least one of titanium and nickel.

3. The semiconductor package of claim 1, wherein the first molding layer includes a protrusion protruding toward the cavity of the second molding layer, and
wherein the first portion of the metal pattern covers an upper surface of the protrusion.

4. The semiconductor package of claim 3, wherein a vertical length of the protrusion has a value between 5 μm and 50 μm.

5. The semiconductor package of claim 3, wherein the protrusion is horizontally spaced from the second molding layer, and
wherein an upper surface of the protrusion is positioned at a level lower than an upper surface of the second molding layer.

6. The semiconductor package of claim 3, wherein the metal pattern further includes:
a second portion connected to the first portion and disposed on a sidewall of the protrusion; and
a third portion connected to the second portion and extending from the second portion onto a lower surface of the second molding layer.

7. The semiconductor package of claim 6, wherein the third portion of the metal pattern is disposed between the first molding layer and the second molding layer, and
wherein the first molding layer and the second molding layer are vertically spaced apart from each other with the third portion of the metal pattern therebetween such that the first molding layer and the second molding layer do not contact one another.

8. The semiconductor package of claim 1, wherein the second molding layer has an inner wall defining the cavity, and
wherein the metal pattern covers the inner wall of the second molding layer.

9. The semiconductor package of claim 1, wherein the first and second molding layers each include an epoxy resin.

10. The semiconductor package of claim 1, wherein the metal pattern has a uniform thickness.

11. A semiconductor package comprising:
a substrate;
a semiconductor chip on the substrate;
a first molding layer covering the semiconductor chip on the substrate and including a protrusion protruding upward;
a second molding layer on the first molding layer and having a cavity formed therein that corresponds to the protrusion; and
a metal pattern on the protrusion in the cavity,
wherein an uppermost end of the metal pattern is disposed at a level equal to or higher than an upper surface of the second molding layer.

12. The semiconductor package of claim 11, wherein the protrusion and the cavity overlap vertically, and
wherein the protrusion of the first molding layer protrudes toward the cavity formed in the second molding layer.

13. The semiconductor package of claim 11, wherein the metal pattern is disposed between a sidewall of the protrusion and an inner sidewall of the second molding layer defining the cavity, and on an upper surface of the protrusion.

14. The semiconductor package of claim 11, wherein a thickness of the metal pattern is between 10 nm and 1 μm.

15. The semiconductor package of claim 11, a thickness of the second molding layer is between 5 μm and 50 μm.

16. The semiconductor package of claim 11, wherein the metal pattern covers an upper surface of the protrusion and a sidewall of the protrusion.

17. The semiconductor package of claim 11, further comprising a bonding wire electrically connecting the substrate and the semiconductor chip,
wherein the first molding layer covers the bonding wire, and
wherein the second molding layer is vertically spaced apart from the bonding wire.

18. The semiconductor package of claim 11, wherein the metal pattern covers an entire lower surface of the second molding layer, and
wherein the first molding layer and the second molding layer are spaced apart from each other with the metal pattern therebetween.

19. A semiconductor package comprising:
a substrate;
a semiconductor chip on the substrate;
a bonding wire electrically connecting the substrate and the semiconductor chip;
a first molding layer covering the semiconductor chip on the substrate and including a protrusion protruding upward;
a second molding layer on the first molding layer and having a cavity formed therein that vertically overlaps the protrusion;
a metal pattern having a first portion disposed on an upper surface of the protrusion and a second portion between the first molding layer and the second molding layer; and
a connection terminal on a lower surface of the substrate,
wherein an uppermost end of the metal pattern is disposed at a level equal to or higher than an upper surface of the second molding layer.

20. The semiconductor package of claim 19, wherein the second molding layer has an inner wall defining the cavity, and
wherein the metal pattern covers the inner wall of the second molding layer.
